(19) United States
(12) Patent Application Publication
(10) Pub. No.: US 2024/0072181 A1
(43) Pub. Date: Feb. 29, 2024

(54) A SOLAR CELL ASSEMBLY

(71) Applicant: REC SOLAR PTE. LTD., Singapore (SG)

(72) Inventors: Jeonghun YU, Singapore (SG); Thein Aung Victor LYNN, Singapore (SG)

(73) Assignee: REC SOLAR PTE. LTD., Singapore (SG)

(21) Appl. No.: 18/259,797

(22) PCT Filed: Dec. 20, 2021
(86) PCT No.: PCT/EP2021/086832

§ 371 Date: Jun. 29, 2023

(30) Foreign Application Priority Data
Dec. 30, 2020 (GB) 2020731.2

(51) Int. Cl. H01L 31/02; H01L 31/0224; H01L 31/18

(52) U.S. Cl. CPC H01L 31/0201; H01L 31/02013; H01L 31/022425; H01L 31/1876

(57) ABSTRACT

A solar cell assembly comprising; a layered structure comprising a photovoltaic element; and an electrode assembly arranged on a surface of the layered structure, the electrode assembly comprising; a plurality of conductive wire portions, a first plurality of conductive elements arranged on the surface of the layered structure; and a second plurality of conductive elements interposed between the plurality of conductive wire portions and the first plurality of conductive elements; wherein the first plurality of conductive elements are configured to form an ohmic contact between the second plurality of conductive elements and the surface of the layered structure, and the second plurality of conductive elements are configured to form an ohmic contact between the first plurality of conductive elements and the plurality of conductive wire portions.

### FIELD OF THE DISCLOSURE

The present disclosure relates to a solar cell assembly, a solar module and to a method of manufacturing a solar cell assembly.

### BACKGROUND

Solar modules for providing electrical energy from sunlight comprise an array of photovoltaic cells, each comprising a semiconductor substrate. The cells are traditionally connected so that electrical current is routed via a grid of finger electrodes on the cell surfaces to a series of wider, perpendicular busbar electrodes which are printed on the front and backside of the cells. From the busbar electrodes, the electrical current flows to a junction box along a series of copper ribbons, each one soldered to a respective busbar electrode.

A general aim for solar cell development is to attain high conversion efficiency balanced by a need for reduced production costs. Efforts to achieve this have focussed, in particular, on the electrode connections between the solar cells in the module and the properties of the semiconductor substrate. However, despite these developments, there remains a need to improve the contact between electrodes of solar cells in order to increase their power conversion efficiency.

### SUMMARY

According to a first aspect there is provided a solar cell assembly comprising:
a layered structure comprising a photovoltaic element; and
an electrode assembly arranged on a surface (e.g. outer surface) of the layered structure, the electrode assembly comprising;
   a plurality of conductive wire portions,
   a first plurality of conductive elements arranged on the surface of the layered structure; and
   a second plurality of conductive elements interposed between the plurality of conductive wire portions and the first plurality of conductive elements;
wherein the first plurality of conductive elements are configured to form an ohmic contact between the second plurality of conductive elements and the surface of the layered structure, and the second plurality of conductive elements are configured to form an ohmic contact between the first plurality of conductive elements and the plurality of conductive wire portions.

The second plurality of conductive elements are configured to provide an electrical pathway between the first plurality of conductive elements and the plurality of conductive wires. Accordingly, the second plurality of conductive elements reduce the contact resistivity of the electrode assembly which thereby increases the fill factor of the solar cell. In this way, the conductive element(s) are configured to reduce resistance losses which would otherwise occur due to the poor contact interface between the plurality of conductive wires and the first plurality of conductive elements arranged on the surface of the layered structure.

It will be understood that the terms ‘conductive’ and ‘insulating’ as used herein, are expressly intended to mean electrically conductive and electrically insulating, respectively. The meaning of these terms will be particularly apparent in view of the technical context of the disclosure, being that of photovoltaic solar cell devices. It will also be understood that the term ‘ohmic contact’ is intended to mean a non-rectifying electrical junction (i.e. a junction between two conductors which exhibits a substantially linear current-voltage (I-V) characteristic).

Optional features will now be set out. These are applicable singly or in any combination with any aspect.

The first and second pluralities of conductive elements may define, respectively, a plurality of finger electrodes and a plurality of elongate busbars that are arranged on (e.g. printed on) the surface of the layered structure to define a ‘solar cell’ of the solar assembly, as would readily be understood by the skilled person. In particular, the plurality of elongate busbars are arranged on top of (e.g. printed on top of) the plurality of finger electrodes. In other words, in an embodiment, the first and second pluralities of conductive elements may form part of the solar cell. In this embodiment, the plurality of conductive wire portions may at least in part form an electrode assembly which is applied to the solar cell. The combination of the solar cell and the electrode assembly may be referred to as a solar cell assembly.

It will also be understood that the first and second pluralities of conductive elements, together with the plurality of conductive wire portions, are configured to work together in order to extract charge carriers from the layered structure. Accordingly, these components define an electrode assembly which when combined with the layered structure defines a solar cell assembly of the present invention. In other words, in an embodiment, the first and second pluralities of conductive elements, with the plurality of conductive wire portions, may at least in part form an electrode assembly which is applied to a solar cell. The combination of the solar cell and the electrode assembly may be referred to as a solar cell assembly.

The layered structure may comprise a front (e.g. frontmost) surface and a back (e.g. backmost) surface. The front surface may be opposite the back surface. The electrode assembly may define a back electrode assembly which is arranged on the back surface of the layered structure. The solar cell assembly may further comprise a front electrode assembly arranged on the front surface of the layered structure opposite the back surface.

The plurality of conductive wire portions may be arranged in a film. The film may be configured to be electrically insulating and/or optically transparent. The film may be configured to provide adhesion between the layered structure and the conductive wire portions so that the wire portions are correctly spaced on the layered structure. In this way, the film enables the wire portions to be correctly aligned with the layered structure, and in particular with respect to the second plurality of conductive elements. The film may provide a mechanical connection between the wire portions and the layered structure. In an exemplary arrangement, the film may not cover all of the surface of the layered structure.

The plurality of conductive wire portions of the back electrode assembly may define a first plurality of conductive wire portions. The film (e.g. insulating and/or optically transparent film) may define a first (e.g. back) film (e.g. insulating and/or optically transparent film).

The front electrode assembly may comprise a second plurality of conductive wire portions. The second plurality of conductive wire portion may be arranged in a second (e.g. front) film (e.g. insulating and/or optically transparent film).

The second plurality of conductive wire portions may be configured to form an ohmic contact with a third plurality of conductive elements of the front electrode assembly. The third plurality of conductive elements may be interposed between the second plurality of conductive wire portions of the front electrode assembly and the front surface of the layered structure.

Only the back electrode assembly may comprise a second plurality of conductive elements, which are interposed between a plurality of conductive wire portions and a first plurality of conductive elements. Put another way, only the back electrode assembly may include the second plurality of conductive elements as defined above. In this way, the back electrode assembly may be configured with two pluralities of conductive elements, each interposed between the first plurality of conductive wire portions and the back surface of the layered structure.

By contrast, the front electrode assembly may only be configured with a single plurality of conductive elements (i.e. the third plurality of conductive elements) which are interposed between the second plurality of conductive wire portions and the front surface of the layered structure. That is, in the front electrode assembly, the second plurality of conductive wires may be electrically connected to the front surface of the layered structure via only the third plurality of conductive elements, i.e. there may be no intervening elements between the second plurality of conductive wires and the front surface of the layered structure other than the third plurality of conductive elements.

On the other hand, in the back electrode assembly, the first plurality of conductive wires may be electrically connected to the back surface of the layered structure via only the first and second pluralities of conductive elements, i.e. there may be no intervening elements between the first plurality of conductive wires and the back surface of the layered structure other than the first and second pluralities of conductive elements.

Accordingly, each conductive element of the second plurality of conductive elements (i.e. of the back electrode assembly) may be configured to form an ohmic contact between a conductive element of the first plurality of conductive elements and a respective conductive wire portion of the first plurality of conductive wire portions. By contrast, each conductive wire portion of the second plurality of conductive wire portions (i.e. of the front electrode assembly) may be configured to form an ohmic contact, directly with a conductive element of the third plurality of conductive elements.

Considering the back electrode assembly, the second plurality of conductive elements have no impact on the shading of the front surface of the layered structure, upon which the majority of the light is incident when the solar cell assembly is in use. By only providing the second plurality of conductive elements on the back surface of the layered structure (i.e. the surface facing away from the incident light), any shading which may be caused by the conductive elements is limited.

The front surface of the layered structure may define the surface of the layered structure upon which light is incident when the solar cell assembly is in use. The back surface of the layered structure will define the surface of the layered structure which is opposite the front surface i.e. the back surface of the layered structure may not be directly exposed to incident light during use. The solar cell assembly may be configured so that reflected light is directed towards the back surface of the layered structure.

Each of the conductive elements of the second plurality of conductive elements may comprise an elongate busbar. The conductive elements/elongate busbars may be configured to extend across the surface of the layered structure so as to form an ohmic contact with each of the plurality of first conductive elements arranged thereon. The second plurality of conductive elements/elongate busbars are formed of an electrically conductive material such that they enable the flow of electrical charge carriers from the at least one of first plurality of conductive elements arranged on the back surface of the layered structure to at least one of the first plurality of conductive wire portions. In this way, each one of the second plurality of conductive elements/elongate busbars may define a current collector of the back electrode assembly.

It will be understood that a known solar cell may be provided with ‘redundancy lines’ (aka angled redundancy lines) that extend a short distance from an edge of the solar cell, and which extend in a direction that is non-parallel to (e.g. perpendicular to or at about 45° to) the finger electrodes. In an embodiment, each redundancy line may extend across less than 20% of the surface (e.g. length or width) of the solar cell, for example, less than 10%, 7.5% or 5% of the surface (e.g. length or width) of the solar cell.

These ‘redundancy lines’ are arranged on the surface of the solar cell so as to help with the alignment of an array of conductive wires across the finger electrodes. Accordingly, these ‘redundancy lines’ are arranged in the same plane as the finger electrodes so that they do not disrupt the contact interface between the conductive wires and the finger electrodes. The electrode assembly according to the present invention is distinguished from solar cells having such ‘redundancy lines’ due to the fact that the conductive elements/elongate busbars are interposed between the first plurality of conductive elements and the plurality of conductive wire portions. In this way, at least a portion of the conductive elements/elongate busbars may be arranged in a plane which is adjacently interposed, but spatially distinct, from the respective planes that are occupied by the conductive wire portions and the finger electrodes. Therefore, the conductive elements/elongate busbars are advantageously configured to provide an ohmic contact between the finger electrodes and the wire portions of the electrode assembly.

Each of the second plurality of conductive elements/elongate busbars may be configured to extend substantially across the surface of the layered structure so as to define ‘full length’ elongate busbars. In an embodiment, each of the second plurality of conductive elements/elongate busbars may be configured to extend across more than 50% of the surface (e.g. length) of the layered structure, for example, more than 60%, 70%, 80%, 90% or 95% of the surface (e.g. length) of the layered structure. In this way, a ‘full length’ elongate busbar may provide an ohmic contact between a wire portion and each of the underlying finger electrodes.

Each of the second plurality of conductive elements/elongate busbars may be configured with a width, an axial length and a depth. Each such conductive element/elongate busbar may be configured such that its axial length is substantially greater than its width. The width and axial length of the conductive element/elongate busbar may be measured in perpendicular directions aligned with the plane of the back surface of the layered structure, and the depth may be measured in a direction which is perpendicular to the plane of the back surface of the layered structure. Each such conductive element/elongate busbar may be configured with a depth such that it protrudes/is upstanding from the back surface of the layered structure.

Each of the second plurality of conductive elements/elongate busbars may be arranged to extend lengthwise across the back surface of the layered structure in a longitudinal direction. These conductive elements/elongate busbars may be spaced apart in a transverse direction across the back surface to define longitudinal-extending spaces between the busbars. These conductive elements/elongate busbars may be parallel or substantially parallel to one another. These conductive elements/busbars may be equally or substantially equally spaced in the transverse direction. Accordingly, the second plurality of conductive elements/busbars may form an array of parallel, transversely spaced (e.g. equally spaced) conductive elements/busbars.

At least one of the second plurality of conductive elements/elongate busbars may have a substantially rectangular (e.g. square) cross-section (perpendicular to its axial length). These conductive elements/elongate busbars may all comprise the same rectangular transverse cross-sectional shape. The transverse cross-section of the/each such conductive element/elongate busbar may be uniform along its axial length.

At least one or each of the second plurality of conductive elements/elongate busbars may be configured with a width that varies along its length. The width of the elongate busbar may vary along its length with its widest portions corresponding to where it overlaps with the underlying finger electrodes. Accordingly, the elongate busbar may be configured with a periodically undulating width, with the widest portions corresponding to those portions which overlap with a finger electrode and the narrowest portions corresponding to the spaces between the finger electrodes. In this way, the elongate busbars may be configured such that the contact area with the finger electrodes is maximised whilst minimising the overall size of the busbars, and thereby reducing the associated material costs.

In an exemplary arrangement, the longitudinal edges of the conductive portions/elongate busbars may comprise a plurality of straight facets. Accordingly, the wire receiving surface of the conductive portions/elongate busbars may define a diamond shape. Alternatively, the longitudinal edges of the conductive portions/elongate busbars may comprise a plurality of curved facets. The wire receiving surface of the conductive portions/elongate busbars may define a scallop shape.

The second plurality of conductive elements/elongate busbars may be formed of an electrically conductive material. The electrically conductive material may be formed of a metallic/metallic alloy material, which may include at least one of Ag, Al and Au. These conductive elements/elongate busbars of the back electrode assembly may be formed using a printed material. The printed material enables it to be conveniently deposited onto the back surface of the layered structure to form the second plurality of conductive elements/elongate busbars.

The printed material may be formed using a printable precursor, such as a conductive paste which may comprise a mixture of metal powder (e.g. Ag, Al, Au powder) and glass frit suspended in a solvent. The printable precursor/conductive paste may be fired, or cured, in order to form the printed second plurality of conductive elements/elongate busbars.

Each of the wire portions in the first plurality of wire portions may be configured with a width, an axial length and a depth. The wire portions may be configured such that its axial length is substantially greater than its width. The width and axial length of the wire portions may be measured in perpendicular directions aligned with the plane of the back surface of the layered structure, and the depth may be measured in a direction which is perpendicular to the plane of the back surface of the layered structure.

Each of the first plurality of wire portions may be arranged to extend lengthwise relative to the back surface of the layered structure in a longitudinal direction. The wire portions may be spaced apart in a transverse direction relative to the back surface to define longitudinal-extending spaces between the wire portions. The wire portions may be parallel or substantially parallel to one another. The wire portions may be equally or substantially equally spaced in the transverse direction. Accordingly, the plurality of conductive wire portions may form an array of parallel, transversely spaced (e.g. equally spaced) wire portions.

Two or more of the wire portions of the first plurality of wire portions may be electrically or physically joined to form a single electrically conductive conduit.

The shape and size of the first and/or second plurality of conductive wire portions, hereinafter also referred to as wire portions, may be chosen to optimise the optoelectronic properties of the front and/or back electrode assemblies, i.e. their electric current collection and layered structure shading characteristics. Each wire portion may have a circular transverse cross-sectional shape (i.e. transverse to the axial length of the wire portion). Alternatively, the wire portions may have different transverse cross-sectional shape, including rectangular, polygonal and triangular, for example. Alternatively, the wire portion cross-section may be an obround shape or an irregular shape.

Each of the conductive wire portions of the first and/or second plurality of conductive wires may be formed of a conductive metal, or metal alloy. Each of the wire portions may be at least partly coated with a coating which comprises an electrically conductive material having a melting point which is lower than that of a core of the wire. Each wire may be completely coated in the alloy coating, or at least partially coated on a side, or sides, which face(s) the layered structure.

The outer coating may comprise a metal alloy formed of at least two or more components. The outer coating alloy may be at least one of a lead based, tin based and bismuth based alloy. The outer coating may comprise a 2-phase, 3-phase or more complex metal alloy.

The wire portion coating may be formed of a metal alloy comprising at least one of Ag, Bi, Cd, Ga, In, Pb, Sn, Ti, etc. The wire portion coating may also comprise an electrically conductive material which is formed of metallic or alloy particles embedded within an organic matrix.

At least one, or each, of the wire portions of the first and/or second plurality of conductive wire portions may be disposed on a surface of the respective first and second insulating optically transparent film. Alternatively, or in addition, at least one of the wire portions may be arranged at least partially within the film. In this way, the at least one wire portion may be embedded within the film such that a surface of the wire portion protrudes from the surface of the film. Alternatively, at least one, or each, of the wire portions may be substantially enveloped (e.g. completely enveloped) within their respective films whilst still being configured to form an electrical contact with the conductive element/elongate busbar upon which they are overlaid.

The first and/or second film may be formed of a polymer material having a high ductility, good insulating characteristics, optical transparency and thermal stability, resistance to shrinkage. Exemplary polymer materials may comprise acetate, epoxy resin, fluororesin, polyamide resin, polysulfone, rayon, polyolefin, plastilene, rayonext, polyethylene terephthalate (PET), polyvinyl fluoride film and modified ethylene tetrafluoroethylene, etc. In an embodiment, the first and/or second film consists of a single layer of material; however, in some other embodiments, the first and/or second film comprises two or more layers wherein two or more of these layers may include different materials and/or material characteristics.

The surface of the film facing the wire portions may be coated with a transparent adhesive. During fabrication of the solar cell assembly, the film may be heated so that the adhesive softens to enable adherence of the film to the wire portions due to an application of force. In this way, the wires may be at least partially embedded in the adhesive. The first and/or second film may be configured to provide structural support for the wire portions when the plurality of conductive wire portions are being handled, prior to being arranged onto the layered structure.

When the front electrode assembly and/or back electrode assembly are assembled with the layered structure, the associated insulating optically transparent film may deform so as to conform to the shape of the wire portions sandwiched between the film and the layered structure. In other words, the front surface of the film may be substantially planar in non-wire regions, and form ridges/protuberances over the wire portions in the wire regions. In this way, each (e.g. longitudinal) wire region of the film may have a convex (e.g. transverse) profile (i.e. a substantially semi-circular profile).

The first insulating optically transparent film of the back electrode assembly may have a front surface (facing towards the layered structure), and a rear surface (facing away from the layered structure) opposite the front surface. At least one wire portion of the first plurality of conductive wire portions may be disposed on the front surface of the first film.

The second insulating optically transparent film of the front electrode assembly may have a front surface (facing away from the layered structure) upon which light is incident in use, and a rear surface (facing the layered structure) opposite the front surface. At least one wire portion of the second plurality of conductive wire portions may be disposed on the rear surface of the second film.

The layered structure may comprise a length and a width. The length of the layered structure may be less than its width. The longitudinal and transverse directions across the back surface of the layered structure may be parallel with the length and width directions of the layered structure, respectively. Hence, the second plurality of conductive elements/elongate busbars and wire portions may be arranged to extend across the length of the layered structure, and to be spaced along its width.

At least one wire portion of the first plurality of conductive wire portions may be arranged to overlay (e.g. partially or completely) an electrically conductive element/elongate busbar of the electrode assembly (e.g. back electrode assembly).

A plurality of the wire portions of the first plurality of conductive wire portions may be configured to overlay (e.g. partially or completely) a corresponding second plurality of conductive elements/elongate busbars.

Each of the wire portions of the first plurality of conductive wire portions may be configured to overlay (e.g. partially or completely) a corresponding conductive element of the second plurality of conductive elements/elongate busbars. For example, each of the wire portions of the first plurality of conductive wire portions may be configured to at least partly overlay a different conductive element/elongate busbar of the second plurality of conductive elements/elongate busbars.

The axial length of at least one wire portion of the first plurality of conductive wire portions may be arranged to be substantially parallel/axially aligned to the axial length of an electrically conductive element (of the second plurality)/elongate busbar upon which it is overlaid.

The axial length of a plurality of the wire portions of the first plurality of conductive wire portions may be configured to be substantially parallel/axially aligned to the axial length of a corresponding second plurality of conductive elements/elongate busbars upon which they are overlaid.

The axial length of each of the wire portions of the first plurality of conductive wire portions may be configured to be substantially parallel/axially aligned to the axial length of a corresponding conductive element of the second plurality of conductive elements/elongate busbars upon which they are overlaid.

The substantial alignment between the/each overlaid conductive element/elongate busbar and the respective conductive wire portion thereby reduces the shading caused by the conductive elements/elongate busbars and the first plurality of conductive wire portions.

The above described substantial alignment between the second plurality of conductive elements/elongate busbars and the first plurality of conductive wire portions also increases the contact area at the interface between these conductive wire portions and these conductive elements/elongate busbars, which thereby reduces the resistivity of the contact. Thus, the solar cell assembly may be configured to maintain a similar short circuit current (i.e. due to the similar shading), whilst increasing the fill factor owing to the reduced resistivity at the contact interface.

According to an exemplary arrangement of the back electrode assembly, the array of parallel, transversely spaced first plurality of conductive wire portions may be overlaid upon i.e. directly superimposed upon the array of parallel, transversely spaced second plurality of conductive elements/elongate busbars.

When at least one conductive element/elongate busbar is overlaid and aligned with at least one conductive wire portion of the first plurality of conductive wire portions, the width of (e.g. at least a first portion of the width of) the conductive element/elongate busbar may be at least equal to a thickness of the conductive wire portion measured in the plane of the surface of the layered structure. For example, the conductive element/elongate busbar may comprise a width, along its entire length, that is at least equal to the thickness of the conductive wire portion.

When the conductive element/elongate busbar is configured with a width (e.g. at least a second portion of the width, and/or at least the first portion of the width) that is equal to the thickness of the conductive wire portion, the back electrode assembly does not introduce extra shading because the conductive elements/busbars have a similar width to that of the conductive wire portions.

The width of (e.g. at least a third portion of the width of) the conductive elements/elongate busbars may be less than a thickness (e.g. width) of the conductive wire portions measured in the plane of the surface of the layered structure. For example, the conductive element/elongate busbar may comprise a width, along its entire length, that is less than the thickness of the conductive wire portion. In embodiments, the width of (e.g. at least the third portion of the width of) the conductive elements/elongate busbars may be only slightly less than the thickness of the conductive wire portions. For example, the width of (e.g. the width of at least the third portion of) the conductive elements/elongate busbars may be around 90% that of the conductive wire portions.

The curved outer surface of the conductive wire portions means that the width of the maximum contact area with the underlying elongate busbars is smaller than the thickness of the conductive wire portions. Therefore, the elongate busbars can be configured with a slightly narrower width and yet still maintain a good ohmic contact, and whilst minimising the effects of shading on the layered structure. For example, the width of (e.g. the width of at least the third portion of and/or the entire length of) the conductive element/elongate busbar may be less than 0.70 mm. For example, the width of (e.g. the width of at least the third portion of and/or the entire length of) the conductive element/elongate busbar may be less than 0.25 mm.

In embodiments, the conductive wire portion may comprise a substantially flat ribbon having a width of between 0.6 mm and 0.7 mm. In this case, the elongate busbars may be configured with a width that is 0.1 mm less than the width of the ribbon so as to reduce shadowing effects of the busbar.

According to an exemplary embodiment, the width of the conductive elements/elongate busbars may be greater than the thickness (e.g. width) of the conductive wire portions. By configuring each of the conductive elements/elongate busbars with a width that is slightly greater than the thickness of the conductive wire, this ensures a good electrical contact, even in the event of a minor misalignment between the respective wires and busbars.

The conductive wire portions in the second plurality of conductive wire portions may be as described above for the first plurality of wire portions.

The first plurality of wire portions and the second plurality of wire portions may be aligned with one another, with the layered structure interposed therebetween.

The first plurality of conductive elements of the electrode assembly (e.g. the back electrode assembly) may comprise a plurality of finger electrodes which are arranged on the back surface of the layered structure (e.g. a plurality of back finger electrodes). The third plurality of conductive elements of the front electrode may comprise a plurality of finger electrodes arranged on the front surface of the layered structure (i.e. a plurality of front finger electrodes).

Each finger electrode of the pluralities of front and/or back finger electrodes may be configured with an axial length which is substantially greater than its width. Both the width and axial length of the finger electrode may be measured in perpendicular directions in the plane of the respective surface of the layered structure. The finger electrodes may extend in a transverse direction which is parallel with the width direction of the layered structure.

The finger electrodes within each of the pluralities of front and/or back finger electrodes may be spaced apart across the respective surface to define transversely-extending spaces between the finger electrodes. The finger electrodes may be spaced apart in a longitudinal direction which is substantially parallel with the length direction of the layered structure. The finger electrodes in each plurality may be substantially parallel to one another. Accordingly, the plurality of back finger electrodes may form an array of parallel, longitudinally spaced (e.g. equally spaced) finger electrodes.

The axial length of at least one finger electrode of the plurality of back finger electrodes may be substantially misaligned (e.g. substantially non-parallel or substantially perpendicular) with the axial length of at least one of the second plurality of conductive elements/elongate busbars which is overlaid upon it. The axial length of at least one finger electrode of the plurality of back finger electrodes may be substantially misaligned (e.g. substantially non-parallel or substantially perpendicular) with the axial length of at least one conductive wire portion of the first plurality of conductive wire portions.

Accordingly, where a conductive element/elongate busbar is axially aligned with an overlaid conductive wire portion, then the axial length of an associated finger electrode may be axially misaligned with both the conductive wire portion and the conductive element/elongate busbar by the same angle of misalignment.

The axial length of the finger electrode may be arranged substantially perpendicular with respect to the axial lengths of the overlaid conductive wire portion and/or the conductive element/elongate busbar. In this way, the finger electrodes can be conveniently arranged so as to optimise the charge collection from the back surface of the layered structure.

The front surface of the layered structure may comprise a different number of finger electrodes to that of the back surface of the layered structure. The back finger electrodes may number at least 80, and/or up to 300.

In general, the finger electrodes may extend substantially across the length of the layered structure. At least one of the plurality of finger electrodes on the front surface of the layered structure may extend only partially across the length of the front surface. The at least one front finger electrodes may extend from an edge of the layered structure, to define shortened front finger electrodes. In this way, the front surface of the layered structure may be provided with a greater number of finger electrodes at the edges where there are fewer wire portions to extract charges from the solar cell. The shortened front finger electrodes may be arranged alternately with the ‘full length’ front finger electrodes, across the width of the layered structure. The shortened front finger electrodes reduce the amount of shading in the middle region of the layered structure. The shortened front finger electrodes may be referred to as “redundancy lines” (aka parallel redundancy lines).

By contrast, each of the back finger electrodes may be configured to extend substantially across the length of the layered structure, so as to define ‘full length’ back finger electrodes. In an embodiment, each of the back finger electrodes may be configured to extend across more than 50% of the surface (e.g. width) of the layered structure, for example, more than 60%, 70%, 80%, 90% or 95% of the surface (e.g. width) of the layered structure. The greater length (and number) of back finger electrodes provides increased charge extraction at the back surface of the layered structure, where shading is not an issue.

According to an exemplary arrangement of solar cell assembly, the array of parallel, transversely spaced plurality of conductive elements/elongate busbars may be overlaid upon i.e. directly superimposed upon and perpendicularly arranged relative to the array of the plurality of back finger electrodes.

The first plurality of electrically conductive elements, e.g. the back finger electrodes, may be formed of an electrically conductive material, i.e. a first electrically conductive material. As described above, the second plurality of conductive elements/elongate busbars may be formed of an electrically conductive material, i.e. a second electrically conductive material, which may be the same or different to the first. The third plurality of electrically conductive elements, e.g. the front finger electrodes may be formed of a third electrically conductive material which may be the same or different to the first, and/or second, electrically conductive material(s).

At least one, or each, of the first, second and third electrically conductive material(s) may be printed materials. The printed first and/or third electrically conductive material enables the formation of finger electrodes having narrow widths and/or depths (relative to their axial lengths) on the respective surfaces of the layered structure. The first and/or third electrically conductive materials may be formed of a metallic/metallic alloy material, which may include at least one of Ag, Al and Au.

It will be appreciated that the first and second plurality of conductive wire portions may be configured to connect together multiple solar cell assemblies within a solar module. For example, the second plurality of conductive wire portions may form part of a foil-wire electrode arrangement (e.g. by supporting the wire portions with an insulating optically transparent film, as described above) comprising a grid of alloy-coated copper wires which connect directly with the finger electrodes arranged on the front surface of the layered structure. This reduces electrical losses and minimises the impact that cracks or cell damage may have on the performance of the solar module. Furthermore, the use of foil-wire electrode arrangements leads to a significant reduction in module production costs and also optical losses arising from the light shading caused by configuring the front surface with conventional busbar electrodes.

It will be understood that the connection between the finger electrodes and the plurality of conductive wires of such foil-wire electrode arrangements may be unreliable which can lead to increased resistivity and high fill factor losses for the solar cell assembly. However, the plurality of conductive elements/elongate busbars which are interposed between first plurality of conductive wires and the finger electrodes on the back surface of the solar cell assembly, reduce the resistivity of the back electrode assembly and thereby increase the fill factor of the solar cell assembly.

The layered structure of the solar cell assembly may comprise a plurality of layers, or elements, wherein at least one of the plurality of layers is formed of a semiconductor material. The photovoltaic element (or layer), may be formed of a silicon wafer so as to define a semiconductor layered structure of the silicon solar cell.

According to an exemplary arrangement of the solar cell assembly, the layered structure comprises a multi-layer semiconductor assembly including a photovoltaic element and at least one emitter layer positioned opposite the photovoltaic element. The at least one emitter layer may be arranged opposite the photovoltaic element to form a p-n junction. The emitter layer may be electrically connected to the front electrode assembly or the back electrode assembly. A first emitter layer may be connected to the front electrode assembly and a second emitter layer may be connected to the back electrode assembly.

It will be appreciated that the layered structure may be configured to define any type of solar cell structure. For example, the layered structure may define a heterojunction type solar cell. Alternatively, the layered structure may define a tandem junction solar cell.

The at least one emitter layer may be arranged towards the front surface of the layered structure. The front electrode assembly may be positioned on the emitter layer. Accordingly, the emitter layer may be arranged between the front electrode assembly and the photovoltaic element of the layered structure.

A back surface field layer may be positioned toward the back surface of the layered structure, i.e. between the photovoltaic element and the back electrode assembly. The back surface field may be configured to extract charge carriers from the photovoltaic element during operation of the solar cell. Accordingly, the back electrode assembly may be positioned on the field layer of the layered structure.

The photovoltaic element may be formed of a semiconductor material, such as silicon. The semiconductor material, or a portion thereof, may be positively or negatively doped (i.e. a p-type or an n-type semiconductor) though not required. The semiconductor material may not be doped (i.e. an intrinsic semiconductor). The silicon used in the layered structure may be crystalline silicon such as single crystal silicon and polycrystalline silicon or amorphous silicon.

The multi-layer semiconductor assembly may comprise an emitter layer comprising a p-type material, and a back surface field layer comprising an n-type material, the emitter layer and the back surface field layer being arranged at opposite sides of the photovoltaic element comprising an n-type material. The front electrode assembly may be electrically connected to the emitter layer and the back electrode assembly may be electrically connected to the back surface field layer. Such an arrangement may define a heterojunction technology (HJT) type solar cell. As such, the emitter layer and the back surface field layer may each be formed of amorphous silicon (a-Si:H) and the photovoltaic element may comprise crystalline silicon (c-Si).

The multi-layer semiconductor assembly may comprise at least one intrinsic layer i.e. comprising an intrinsically doped semiconductor. The at least one intrinsic layer may be arranged between the emitter layer and the photovoltaic element to form a front-side passivation layer. Alternatively, or in addition, the at least one intrinsic layer may be arranged between the photovoltaic element and the back surface field layer to form a back-side passivation layer. The at least one intrinsic layer may be formed of amorphous silicon.

When the semiconductor material is of an n-type, it may be configured to contain impurities of a group V element such as phosphor (P), arsenic (As), and antimony (Sb). When the semiconductor material is of a p-type, it may contain impurities of a group Ill element such as boron (B), gallium (Ga), and indium (In). Alternatively, the semiconductor material may be formed of materials other than silicon.

The emitter layer formed in the layered structure may define an impurity region of a second conductive type (for example, a p-type) opposite the first conductive type (for example, an n-type) of the photovoltaic element, and thus forms a p-n junction along with the photovoltaic element.

The interface formed between the p-type and n-type materials at the p-n junction causes excess electrons and holes to diffuse to the n-type and p-type materials, respectively. This relative movement of the charge carriers results in the formation a depletion region (e.g. a space charge region) at the p-n junction. A built-in potential difference is formed across the depletion region once a thermal equilibrium condition is reached.

During operation of the solar cell, a plurality of electron-hole pairs produced by light incident on the substrate is separated into electrons and holes by the electric filed created by the built-in potential difference resulting from the p-n junction. Then, the separated electrons move (e.g. tunnel) to the n-type semiconductor, and the separated holes move to the p-type semiconductor. Thus, when the photovoltaic element is n-type and the emitter is p-type, the separated holes and electrons move to the emitter and the photovoltaic element, respectively. Accordingly, the electrons become majority carriers in the photovoltaic element, and the holes become majority carriers in the emitter.

According to an alternative arrangement, the emitter layer may be of the n-type and the photovoltaic element may be of the p-type to form a p-n junction therebetween. In this instance, the separated holes and the separated electrons move to the photovoltaic element and the emitter layer, respectively.

The front surface(s) of the layered structure may be textured to form a textured surface corresponding to an uneven surface or having uneven characteristics. In this instance, an amount of light incident on the layered structure increases because of the textured surface of the layered structure, and thus the efficiency of the solar cell is improved.

The layered structure may further comprise an anti-reflection layer, or coating, arranged at the front and/or back surfaces of the layered structure. The, or each, anti-reflection layer may have a single-layered structure or a multi-layered structure. The anti-reflection layer may be formed of silicon nitride (SiNx) and/or silicon oxide (SiOx). Alternatively, the anti-reflection layer may be formed of a transparent conductive oxide (TCO), such as indium tin oxide (ITO), which has been textured to provide an anti-reflective surface. The anti-reflection layer advantageously reduces the reflectance of light incident on the solar cell and increases selectivity of a predetermined wavelength band, thereby increasing the efficiency of the solar cell.

The layered structure may comprise a transparent conductive oxide coating arranged at the front and/or back surfaces of the layered structure. The transparent conductive oxide coating may be electrically connected to at least one of the emitter layer, the intrinsic layer and the photovoltaic element of the layered structure. The transparent conductive oxide coating may be configured to increase lateral carrier transport to finger electrodes arranged on the respective surfaces of the layered structure. The transparent conductive oxide coatings are particularly advantageous in heterojunction type devices which comprise layers formed of amorphous silicon which exhibits poor carrier mobility.

According to a second aspect there is provided a solar module comprising a plurality of solar cells according to the first aspect. The plurality of solar cells may be electrically coupled together.

A first solar cell may be electrically coupled to a second solar cell. As such, a plurality of conductive wire portions of an electrode assembly of the first solar cell may be electrically coupled to a plurality of conductive wire portions of an electrode assembly of the second solar cell. According to an exemplary arrangement, the second plurality of conductive wire portions of the front electrode assembly of the first solar cell may be electrically coupled to the first plurality of conductive wire portions of the back electrode assembly of the second solar cell. Accordingly, the two pluralities of conductive wire portions may form an electrical connection between two or more solar cells in a module.

The first plurality of conductive wire portions of the back electrode assembly of the first solar cell may be physically and/or electrically connected, e.g. integrally formed, with the second plurality of wire portions of the front electrode assembly of the second solar cell. In this way, the plurality of conductive wire portions may provide a direct electrical connection between the first and second solar cells, which thereby increases the flow of charge therebetween. Configuring the conductive wire portions in this way removes the need to provide separate connections (such as copper ribbons) between neighbouring solar cells, which thereby reduces the number and complexity of manufacturing steps required to fabricate the solar module.

In an embodiment, the third plurality of conductive elements of front electrode assembly of the first solar cell is connected to the first plurality of conductive elements of the back electrode assembly of the second solar cell via only the first and second plurality of conductive wire portions and the second plurality of conductive elements.

The solar module may comprise a frame in which to house the plurality of solar cell assemblies. The frame may comprise a front plate and a back plate which are arranged, respectively, on the front and back sides of the plurality of solar cell assemblies. At least one or each of the front and back plates may be formed of glass (e.g. a glass sheet). The solar module may comprise an encapsulant which may be configured to provide adhesion between the front and back plates and the plurality of solar cell assemblies. In this way, the encapsulant may be arranged between the glass sheet of the solar module, and an insulating optically transparent film of one of the plurality of solar cell assemblies. The encapsulant may be configured to prevent the ingress of moisture into the solar module. Accordingly, the encapsulant may be formed of ethylene vinyl acetate (EVA), or any other suitably moisture resistant material.

According to a third aspect there is provided a method for manufacturing a solar cell according to the first aspect comprising:
providing a layered structure comprising a photovoltaic element; and
arranging an electrode assembly onto a surface of the layered structure, wherein arranging the electrode assembly comprises:
   configuring a first plurality of conductive elements onto the surface of the layered structure to form an ohmic contact therewith;
   configuring a second plurality of conductive elements onto the first plurality of conductive elements to form an ohmic contact therewith; and
   arranging a plurality of conductive wire portions onto the second plurality of conductive elements to form an ohmic contact therewith. Optionally, the plurality of conductive wire portions are arranged in a film (e.g. an insulating and/or optically transparent film).

The layered structure may comprise a back (e.g. backmost) surface and a front (e.g. frontmost) surface being opposite the back surface. Accordingly, the method may comprise arranging the electrode assembly onto the back surface of the layered structure to define a back electrode assembly. The method may further comprise arranging a front electrode assembly onto the front surface of the layered structure.

The plurality of conductive wire portions of the back electrode assembly may define a first plurality of conductive wire portions (e.g. arranged in a first insulating and/or optically transparent film). In such an arrangement, the method of arranging the front electrode assembly may comprise configuring a third plurality of conductive elements onto the front surface of the layered structure to form an ohmic contact therewith, and arranging a second plurality of conductive wire portions onto the third plurality of conductive elements to form an ohmic contact therewith. The second plurality of conductive wire portions may be arranged in a second film (e.g. insulating and/or optically transparent film).

Only the method of arranging the back electrode assembly may comprise configuring a second plurality of conductive elements interposed between a plurality of conductive wire portions and a first plurality of conductive elements. That is, in the method of arranging the front electrode assembly, the second plurality of conductive wires may be connected to the front surface of the layered structure via only the third plurality of conductive elements, i.e. there may be no intervening elements between the second plurality of conductive wires and the front surface of the layered structure other than the third plurality of conductive elements. On the other hand, in the method of arranging the back electrode assembly, the first plurality of conductive wires may be connected to the back surface of the layered structure via only the first and second pluralities of conductive elements, i.e. there may be no intervening elements between the first plurality of conductive wires and the back surface of the layered structure other than the first and second pluralities of conductive elements.

The method of configuring the third plurality of conductive elements onto the front surface of the layered structure may comprise depositing (e.g. directly) a plurality of elongate finger electrodes onto the front surface, i.e. a plurality of front finger electrodes. Similarly, the method of configuring the first plurality of conductive elements onto the back surface of the layered structure may comprise depositing (e.g. directly) a plurality of elongate finger electrodes onto the back surface, i.e. a plurality of back finger electrodes.

The second plurality of conductive elements may be configured to define a plurality of elongate busbars. The method may comprise depositing (e.g. directly) at least one of the conductive elements on top of (i.e. overlaying) at least one of the plurality of elongate finger electrodes arranged on the back surface.

The method of depositing the plurality of back finger electrodes may comprise depositing (e.g. directly) a first electrically conductive material onto the back surface of the layered structure. The method of depositing the second plurality of conductive elements/elongate busbars may comprise depositing (e.g. directly and indirectly) a second electrically conductive material onto the back surface of the layered structure to form the plurality of elongate busbars. That is, in areas of the back surface on which back finger electrodes are present, the elongate busbars may be deposited directly on the back finger electrodes and, therefore, indirectly on the back surface; however, in areas of the back surface on which back finger electrodes are not present, the elongate busbars may be deposited directly on the back surface. The method of depositing the plurality of front finger electrodes may comprise depositing (e.g. directly) a third electrically conductive material onto the front surface of the layered structure.

At least one of the first, second and third electrically conductive materials may be deposited by various methods including evaporation, plating, printing etc. For example, the first, second and third electrically conductive materials may comprise a first, second and third printed material, respectively.

The method of depositing the first electrically conductive material may comprise printing a first printable precursor of the first printed material onto the back surface of the layered structure. The method may further comprise curing the first printable precursor according to a first firing process to form the conductive elements/elongate busbars.

The method of depositing the second electrically conductive material may comprise printing a second printable precursor of the second printed material onto the back surface of the layered structure. The method may further comprise curing the second printable precursor according to a second firing process to form the plurality of back finger electrodes.

The method of depositing the third electrically conductive material may comprise printing a third printable precursor of the third printed material onto the front surface of the layered structure. The method may further comprise curing the third printable precursor according to a third firing process to form the plurality of front finger electrodes.

The method of curing at least one of the first, second and third printable precursor(s) may comprise firing the printable precursor, arranged on the respective surface of the layered structure, in a furnace. At least one of the first, second and third printable precursor(s) may comprise a metal paste which may be obtained by mixing a metal powder and glass frit together with a suitable solvent.

The first printable precursor (and thus the first electrically conductive material) used to form the plurality of back finger electrodes may be different to the second printable precursor which is used to form the electrically conductive elements/busbars. As such, the method may comprise printing the first printable precursor onto the back surface of the layered structure then firing the layered structure, according to the first firing process, to form the plurality of back finger electrodes. The method may further comprise depositing the second printable precursor onto the back surface, so that it at least partially overlays at least one of the elongate back finger electrodes, then firing the layered structure, according to the second firing process, to form the plurality of conductive elements/elongate busbars.

The first, second and third electrically conductive materials may each/all comprise different chemical compositions. The first, second and third firing processes may each/all comprise different firing parameters, such as the firing temperature.

The method may comprise depositing the second plurality of conductive elements/elongate busbars so that the axial length of at least one of the conductive elements may be substantially non-parallel (e.g. substantially perpendicular) with the axial length of at least one of the finger electrodes, upon which it is overlaid. The method may comprise depositing the second plurality of conductive elements/elongate busbars such that they are arranged perpendicular to the plurality of back finger electrodes.

The method may comprise depositing the second plurality of conductive elements/elongate busbars at designated positions on the back surface of the layered structure such that they can receive the first plurality of conductive wire portions, i.e. wire receiving positions. Each of the wire receiving position(s) may be determined based on the configuration (i.e. lateral spacing) of the wire portions within the first plurality of the conductive wire portions. In this way, the method ensures that the second plurality of conductive elements are arranged on the back surface of the layered structure so that they can be overlaid (e.g. partly or completely) by the first plurality of conductive wire portions.

Once the second plurality of conductive elements/elongate busbars are deposited onto the finger electrodes arranged on the back surface of the layered structure, the first plurality of conductive wire portions may be overlaid (e.g. partly or completely) onto corresponding second plurality of conductive elements/elongate busbars.

The method may comprise configuring at least one wire portion of the first plurality of conductive wire portions to overlay (e.g. partly or completely) an electrically conductive element (of the second plurality)/elongate busbar of the back electrode assembly.

The method may comprise configuring a plurality of the wire portions of the first plurality of conductive wire portions to overlay (e.g. partly or completely) a corresponding second plurality of conductive elements/elongate busbars.

The method may comprise configuring each of the wire portions of the first plurality of conductive wire portions to overlay (e.g. partly or completely) a corresponding (e.g. a different) conductive element of the second plurality of conductive elements/elongate busbars.

The method may further comprise arranging the axial length of at least one wire portion of the first plurality of conductive wire portions to be parallel/axially aligned (or substantially parallel/axially aligned) to the axial length of an electrically conductive element (of the second plurality)/elongate busbar of the back electrode assembly upon which it is overlaid.

The method may comprise configuring a plurality of the wire portions of the first plurality of conductive wire portions such that their axial lengths are parallel/axially aligned (or substantially parallel/axially aligned) to the axial lengths of a corresponding second plurality of conductive elements/elongate busbars upon which they are overlaid.

The method may comprise configuring each of the wire portions of the first plurality of conductive wire portions such that their axial lengths are parallel/axially aligned (or substantially parallel/axially aligned) to the axial length of a corresponding conductive element of the second plurality of conductive elements/elongate busbars upon which they are overlaid.

Once the first and/or second plurality of conductive wire portions has been overlaid onto the respective front and back surfaces of the layered structure, the method may further comprise heating the conductive wire portions in order to form an ohmic contact with the underlying surface.

The method may comprise heating the first plurality of conductive wire portions to melt at least a portion of a coating of the wire portion. The portion of melted wire coating may be configured to form an ohmic contact with at least one of the plurality of conductive elements/elongate busbars of the back electrode assembly, upon which the wire is overlaid.

The method may comprise heating the second plurality of conductive wire portions to melt at least a portion of a coating of the wire portion. The portion of melted wire coating may be configured to form an ohmic contact with at least one of the plurality of front finger electrodes, upon which it is overlaid.

The respective coatings of the wire portions of the first and/or second plurality of conductive wire portions, may be comprised of materials which have melting points which are lower than the materials from which the core of the respective wire portions are formed. The coatings of the wire portions from the first and/or second plurality of conductive wire portions may be heated separately or during the same heating process.

The front and back first pluralities of conductive elements (e.g. the front and back finger electrodes) may be deposited simultaneously (i.e. using a single deposition process) or they be deposited separately. The second plurality of conductive elements (e.g. the elongate busbars) may be deposited in separate deposition process, once the first plurality of conductive elements are deposited.

The curing temperature for at least one or each of the first and second pluralities of conductive elements may be up to 300° C. In an exemplary embodiment in which the layered structure defines a HJT solar cell structure, the curing step may be configured at a temperature of less than 200° C. In an exemplary arrangement, the curing temperature may be at least 145° C. The curing temperature may be up to 165° C.

The skilled person will appreciate that except where mutually exclusive, a feature or parameter described in relation to any one of the above aspects may be applied to any other aspect. Furthermore, except where mutually exclusive, any feature or parameter described herein may be applied to any aspect and/or combined with any other feature or parameter described herein.

### BRIEF DESCRIPTION OF THE DRAWINGS

Embodiments will now be described by way of example only, with reference to the Figures, in which:

FIG. 1 is a close up sectional side view of the solar module comprising a solar cell;

FIGS. 2A and 2C are plan views of the top (front) and bottom (rear) of the solar cell of FIG. 1, respectively;

FIGS. 2B and 2D are both transverse section views taken at different locations through the solar cell shown in FIGS. 2A and 2C;

FIG. 3 is perspective sectional view of a semiconductor layered structure of the solar cell of FIG. 1;

FIG. 4a is a plan view of the bottom (rear) of a solar cell which comprises an alternative configuration of busbars;

FIG. 4b is a close-up of the bottom (rear) of the solar cell shown in FIG. 4a;

FIG. 5 is a plan view of the bottom (rear) of a solar cell which comprises an alternative configuration of busbars; and

FIG. 6 is a flowchart illustrating a method of manufacturing the solar cell of FIG. 1.

### DETAILED DESCRIPTION

Aspects and embodiments of the present disclosure will now be discussed with reference to the accompanying figures. Further aspects and embodiments will be apparent to those skilled in the art.

In the drawings, the thickness of layers, films, etc., are exaggerated for clarity. Furthermore, it will be understood that when an element such as a layer, film, region, or substrate is referred to as being “on” another element, it can be directly on the other element or intervening elements may also be present. In contrast, when an element is referred to as being “directly on” another element, there are no intervening elements present.

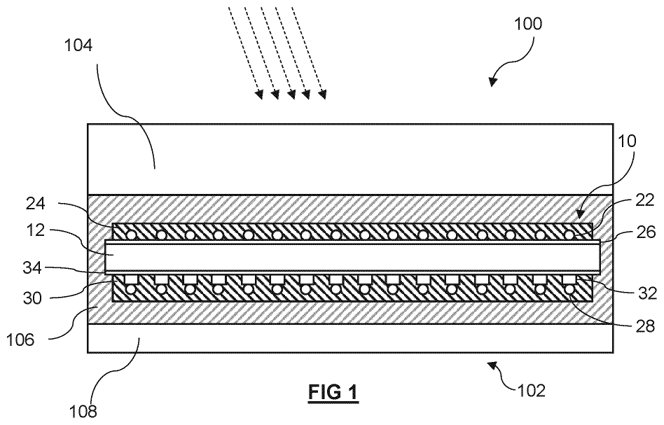

FIG. 1 shows a solar cell 10 according to the present invention, which is arranged within a support assembly 102 of a solar panel. A front plate 104 of the support assembly 102 comprises a transparent (e.g. glass) sheet which is configured to allow light to pass through into a central chamber 106 in which the solar cell 10 is mounted. The arrows at the top of FIG. 1 show the direction of the solar radiation which is incident upon the solar cell 10.

A back plate 108 of the support assembly 102 is arranged to enclose the solar cell 10 within the central chamber 106. The back plate 108 comprises a reflective sheet which is configured to reflect any light which is incident upon its upper surface, back towards the solar cell 10. The central chamber 106 is filled with an encapsulating material (the shaded area shown in FIG. 1) which prevents ingress of external liquid or gaseous entrants.

The solar cell 10 is one of a plurality of solar cells (not shown) which are arranged within the support assembly 102. Each of the plurality of solar cells 10 are electrically coupled together in one or more strings to define a solar module 100.

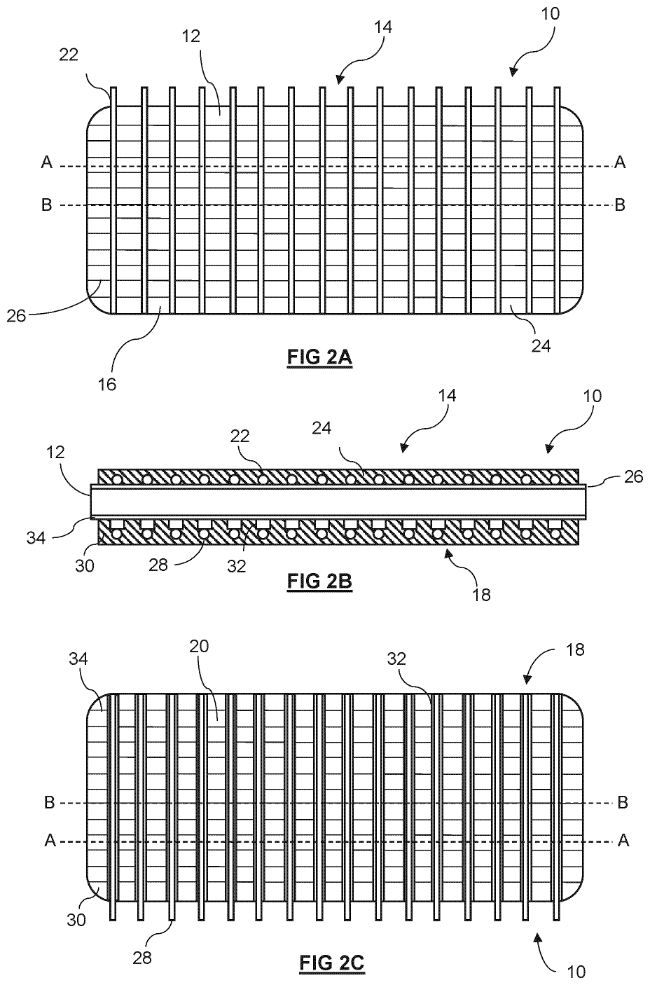

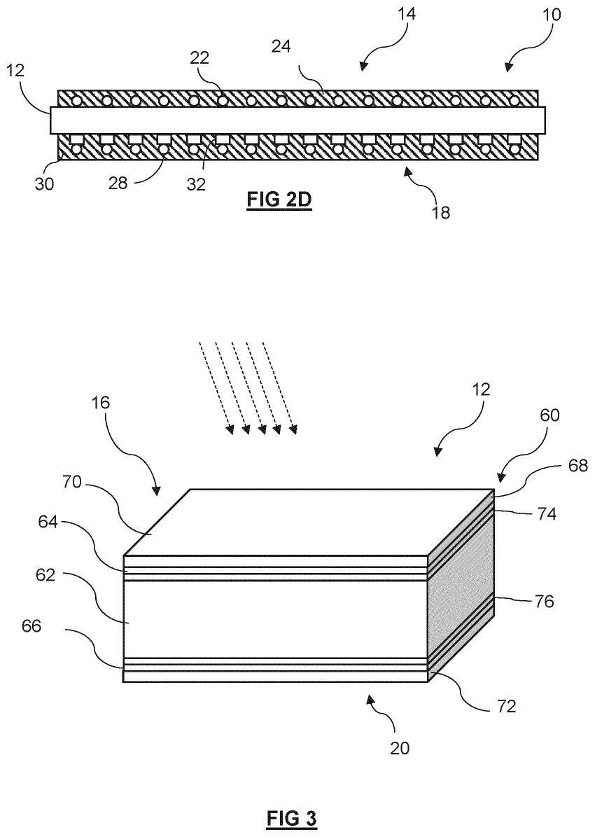

FIGS. 2A and 2C illustrate the top (front) and bottom (rear) view of the solar cell 10, whereas FIGS. 2B and 2D show transverse sections of the solar cell 10 taken, respectively, along the dashed lines B-B and A-A, as shown in FIGS. 2A, 2C. The solar cell 10 includes a layered structure 12, a front electrode assembly 14 arranged on a front surface 16 of the layered structure 12, and a back electrode assembly 18 arranged on a back surface 20 of the layered structure 12. The solar cell 10 has a length which is the vertical dimension of FIGS. 2A and 2C, and a width which is the horizontal dimension of FIGS. 2A and 2C.

The front surface 16 defines a surface of the layered structure 12 on which light is incident when the solar cell 10 is in use. The back surface 20 defines a surface of the layered structure 12 which is opposite to the front surface 16, as shown in FIG. 2B.

As will be described further below, the layered structure 12 is a multi-layer semiconductor assembly configured to generate electrical charge carriers from the absorption of incident radiation. The front and back electrode assemblies 14, 18 are each configured for mounting to the layered structure 12, and conducting away the electrical charge carriers generated by the layered structure 12.

This back electrode assembly 18 comprises a first plurality of conductive wire portions 28 arranged in a first insulating optically transparent film 30, a first plurality of conductive elements 34 arranged on the back surface 20 of the layered structure 12, and a second plurality of conductive elements 32 interposed between the first plurality of conductive wire portions 28 and the first plurality of conductive elements.

The second plurality of conductive elements 32 are configured to form ohmic contacts between the first plurality of conductive wire portions 28 and first plurality of conductive elements 34, which define a plurality of back finger electrodes 34 arranged on the back surface 20 of the layered structure 12.

The front electrode assembly 14 comprises a second plurality of conductive wire portions 22 arranged in a second insulating optically transparent film 24, as shown in FIG. 2B. The second plurality of wire portions 22 are configured to overlay a third plurality of conductive elements 26, which define a plurality of front finger electrodes 26 arranged on the front surface 16 of the layered structure 12. The wire portions 22 are configured to form an ohmic contact with the finger electrodes 26.

Only the back electrode assembly 18 includes a second plurality of conductive elements 32 interposed between the respective finger electrodes 34 and conductive wire portions 28. The front electrode 16 is configured such that the second plurality of conductive wire portions 22 form a direct contact with the finger electrodes 26 arranged on the front surface 16 of the layered structure 12, as shown in FIG. 2B.

By contrast, the second conductive elements 32 of the back electrode assembly 18 are configured to provide an electrical pathway between the finger electrodes 34 on the back surface 20 of the layered structure 12 and the first plurality of conductive wire portions 28. Accordingly, the conductive elements 32 reduce the contact resistivity of the back electrode assembly 18 which thereby increases the fill factor of the solar cell 10. In this way, the conductive elements 32 are configured to reduce resistance losses that would be present if the first plurality of conductive wire portions 28 were configured to contact directly with the plurality of back finger electrodes 34.

The conductive elements 32 are formed of an electrically conductive material such that they are configured to allow electrical charge carriers to flow between the first plurality of conductive wire portions 28 and the finger electrodes 34 on the back surface 20 of the layered structure 12. In this way, each of the conductive elements 32 defines a current collector of the back electrode assembly 18.

Each of the conductive elements 32 comprises an elongate busbar 32 having a width, length and depth. The length of each busbar 32 defines an axial length which is substantially greater than its width. Both the width and the length of the busbar 32 are measured in a direction aligned with the plane of the back surface 20 of the layered structure 12.

The dimensions of each busbar 32 are substantially the same as that of every other busbar 32. For example, the busbars 32 have a common depth such that they each protrude from the back surface 20 of the layered structure 12 by the same amount. The depth of the each busbar 32 is measured in a direction which is perpendicular to the plane of the back surface 20 of the layered structure 12 (the vertical direction shown in FIG. 2B). Furthermore, each of the busbars 32 has a rectangular cross-section (perpendicular to its length).

With reference to FIGS. 2A, 2B and 2C, the arrangement of each of the pluralities of finger electrodes 26, 34, wire portions 22, 28 and busbars 32 will now be described in more detail.

The pluralities of front and back finger electrodes 26, 34 are arranged to extend across the layered structure 12 in the transverse direction (the horizontal direction in FIG. 2A) and are equally spaced apart in the longitudinal direction (the vertical direction in FIG. 2A).

The finger electrodes arranged on each of the front and back surfaces 16, 20 of the layered structure 12 are arranged in parallel with each other. As shown in FIGS. 2A and 2C, each of the pluralities of front and back finger electrodes 26, 34 comprises twelve electrodes. However, it is to be understood that in some other embodiments, the number of front and back finger electrodes 26, 34 may be different, for example, there may be eighty finger electrodes on each of the front and back surfaces 16, 20. It will be appreciated that the number of finger electrodes may be even greater (e.g. more than 250) without departing from the scope of the present invention. The number of elongate busbars 32 is between 4 and 20, and the number of wire portions 28, 22 is the same as the number of elongate busbars 32.

Each one of the finger electrodes arranged on the front surface 16 of the layered structure 12 is aligned with a corresponding electrode from the plurality of back finger electrodes 34.

The wire portions of the first and second plurality of conductive wire portions 28, 22 are parallel and extend lengthwise relative to the back surface 20 of the layered structure 12 in a longitudinal direction (the vertical direction in FIG. 2A). The wire portions within each of the pluralities of wires portions 28, 22 are also equally spaced apart in a transverse direction relative to the back surface 20 of the layered structure 12 (the horizontal direction in FIG. 2A) to define longitudinal-extending spaces between the wire portions. Accordingly, each of pluralities of conductive wire portions 28, 22 defines an array of parallel, transversely spaced wire portions.

Each of the wire portions in the second plurality of conductive wire portions 22 is aligned with a corresponding wire portion from the first plurality of conductive wire portions 28. The first and second plurality of wire portions 28, 22 each comprise sixteen wire portions, arranged on opposite sides of the layered structure 12. Again, in some other embodiments, a different number of wire portions may be present.

Turning now to the plurality of elongate busbars 32 which extend lengthwise across the back surface 20 of the layered structure 12 in a longitudinal direction (the vertical direction in FIG. 2A). Similar to the wire portions, the busbars 32 are also arranged parallel to one another, and are equally spaced in a transverse direction (the horizontal direction in FIG. 2A). Hence, the spacing between the busbars 32 is such that it defines an array of longitudinal-extending spaces therebetween.

According to the above described arrangement, it will be understood that the pluralities of front and back finger electrodes 26, 34 are arranged perpendicular to the first and second plurality of conductive wire portions 22, 28, and also the plurality of elongate busbars 32, as shown in FIGS. 2A and 2C.

As illustrated in FIGS. 2B and 2C, the back electrode assembly 18 is provided with sixteen busbars 32. Each of the sixteen busbars is overlaid with a conductive wire portion from the first plurality of conductive wire portions 28. An axial length of each of the wire portions of the first plurality of conductive wire portions 28 is axially aligned to an axial length of a corresponding busbar of the plurality of elongate busbars 32 upon which they are overlaid. As such, the first plurality of conductive wire portions 28 are directly superimposed on top of the plurality of elongate busbars 32 on the back surface 20 of the layered structure 12. Advantageously, the alignment between the busbars 32 and wire portions 28 limits the proportion of the additional shading which is caused by the inclusion of the busbar 32.

The parallel alignment between the busbars 32 and the wire portions 28 also increases the contact area at the interface between the conductive wire portion and the elongate busbar, which thereby reduces the resistivity of the contact. Thus, the solar cell 10 is configured to maintain a similar short circuit current (i.e. due to the similar shading), whilst increasing the fill factor owing to the reduced resistivity at the contact interface.

The width of each of the elongate busbars 32 is less than 0.25 mm, which is significantly less than the width of a busbar on a conventional solar cell. The narrower width of the busbars enables more busbars 32 to be arranged across the back surface 20 of the layered structure 12 compared to a conventional busbar arrangement. The greater number of busbars 32 thereby creates more current extraction paths within solar cell 10.

Furthermore, each of busbars 32 is configured with a width that is slightly greater than the thickness of the overlying conductive wire portion 28. The greater width of the elongate busbar 32 ensures a good electrical contact at the interface between the conductive wire portion 28 and elongate busbar, which reduces the resistivity of the connection between the first plurality of conductive wire portions 28 and back finger electrodes 32.

By configuring each of the elongate busbars 32 with a width that is slightly wider than the thickness of the conductive wire portion, this ensures a good electrical contact, even in the event of a minor misalignment between the wire portions and busbars during fabrication of the back electrode assembly 18.

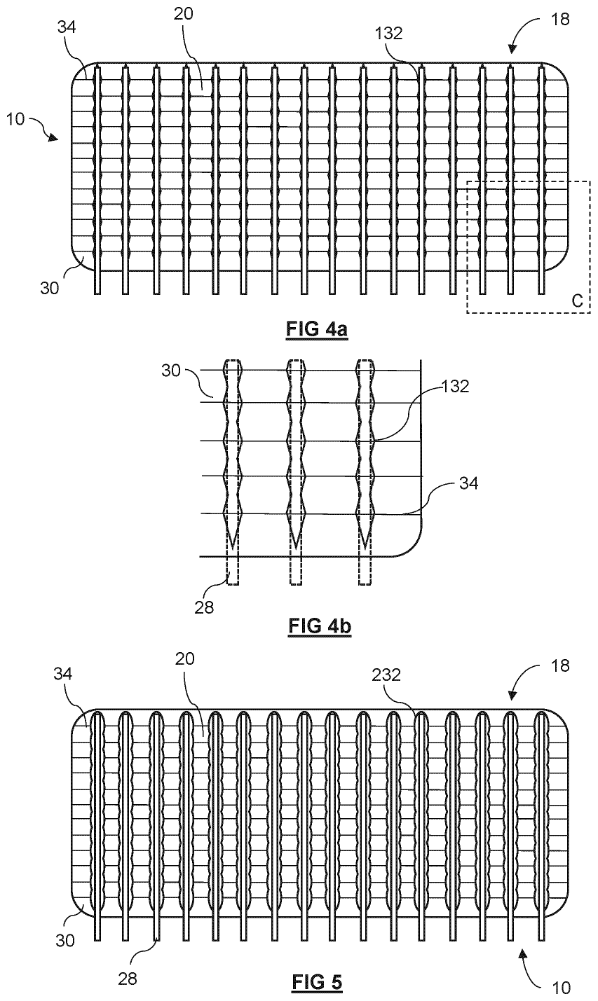

The elongate busbars 32 shown in FIG. 2C are configured with straight longitudinal edges. According to an alternative arrangement of the invention, the longitudinal edges may be configured to comprise a plurality of straight or curved facets, as shown in FIGS. 4A and 5, respectively. With particular reference to FIG. 4B, the wire receiving surface of each of the elongate busbars 132 defines a periodic or repeating diamond shape. Alternatively, the wire receiving surface may comprise a plurality of curved facets so as to define a periodic (or repeating) scalloped shape, as shown in FIG. 5.

In each of the exemplary arrangements shown in FIGS. 4A, 4B and 5, the widest portions of the elongate busbars 132, 232 correspond to those portions which overlap with a finger electrode 32 and the narrowest portions correspond to the spaces between the finger electrodes 32. In this way, the elongate busbars 132, 232 are configured to maximise the contact area with the finger electrodes 32 whilst minimising the overall size of the busbars, and thereby reducing the associated material costs.

The elongate busbars 32 are formed of an electrically conductive material, which is formed of a metallic alloy comprising Ag. The electrically conductive material is a printed material, which enables the busbars 32 to be conveniently deposited onto the back surface 18 of the layered structure 12. The printed material is formed using a printable precursor, such as a conductive paste, which comprises a mixture of silver metal powder and glass frit suspended in a solvent. As will be described in more detail below, the conductive paste may be fired, or cured, in order to form the elongate busbars.

The first and second plurality of finger electrodes 26, 34 are each formed using a printed conductive material similar to that which is used to form the plurality of elongate busbars 32.

The conductive wire portions 22, 28 each have a circular transverse cross-sectional shape (i.e. transverse to the axial length of the wire portion), as shown in FIG. 2A. Each of the wire portions is formed of an axial core which is made from a conductive metal alloy. The core of the wire portion is coated in an outer conductive coating.

The core of the wire portion is formed of copper and the outer coating is formed of a material which has a melting point that is lower than that of the core. The outer coating may comprise a metal alloy, such as a lead based alloy.

According to an exemplary arrangement of the solar cell 10, each of the first and second plurality of conductive wire portions 28, 22 is attached to a surface of its respective film 30, 24 that faces the layered structure 12. This “layered-structure-facing” surface of each film 30, 24 is coated with an adhesive which adheres the wire portions to their respective films 30, 24.

With reference to FIG. 2D, in the case of the front electrode assembly 14, the film 24 is arranged to contact the front surface of the layered structure 12 in the areas in-between the wire portions 22 and the front finger electrodes 26. In the case of the back electrode assembly 18, the film 30 is arranged to contact the back surface 20 of the layered structure 12 in the areas in-between the wire portions 28, the elongate busbars 32 and the back finger electrodes 34.

In an embodiment of the solar cell 10, at least one, or each, of the first and second films 30, 24 are configured to at least partially (e.g. completely) envelope, or surround, the respective wire portions 28, 22 and the respective finger electrodes 34, 26, as shown in FIGS. 1 and 2B. In the case of the back electrode assembly 18, the film 30 may also at least partially (e.g. completely) envelope the elongate busbars 32.

The first and second films 30, 24 are arranged to provide adhesion between the layered structure 12 and the conductive wire portions 28, 22 so that the wire portions are correctly arranged on the layered structure 12 (i.e. aligned with the elongate busbars and finger electrodes). In an exemplary embodiment, the first and second films 30, 24 may not fully cover the surface of the layered structure 12.

Whilst the first and second films 30, 24 shown in the drawings comprise substantially planar bottom and top surfaces, respectively. It will be understood that the films may be configured to conform to the structural components of their respective electrodes. For example, the film 30 of the back electrode assembly 18 may conform to the finger electrodes 34, busbars 32 and wire portions 28 which are arranged on the back surface 20 of the layered structure 12. According to this exemplary arrangement, the film 30 may be comprised of elongate channels recessed towards the layered structure in the regions of the back surface 20 in-between wire portions and busbars, and may form ridges/protuberances over the electrode structures (e.g. busbars and wire portions) where they are present.

The first film 30 is applied with heat and pressure onto the bottom of the layered structure so the film 24 will conform to the elongate busbars and the back finger electrodes. The second film 24 may also be applied with heat and pressure onto the top of the layered structure so that it conforms to the front finger electrodes arranged thereon.

According to an alternative exemplary arrangement, the films 30, 24 may comprise channels, arranged on their respective layered structure facing surfaces. The channels may be configured to provide a tight fit around the corresponding elongate busbars and finger electrodes.

The first and second films 30, 24 are generally thinner than the conductive wire portions 28, 22. For example, the conductive wire portions may have a thickness of around 200 μm to 300 μm, whereas the films have a thickness of around 100 μm.

The first and second films 30, 24 are each formed of a polymer material having a high ductility, good insulating characteristics, optical transparency and thermal stability, resistance to shrinkage. An exemplary polymer material is comprised of modified ethylene tetrafluoroethylene.

FIG. 3 is a sectional view of the layered structure 12 from the solar cell 10 according to FIGS. 2A, 2B and 2C. In this view, the layered structure 12 is shown isolated from the front and back electrodes 14, 18. It is to be understood that FIG. 3 illustrates an exemplary layered structure 12 and that, in some other embodiments, the layered structure may differ from that shown in FIG. 3. For example, in some other embodiments, one or more layers may be absent, one or more layers may be combined together, and/or additional layers may be added, provided that the layered structure 12 can continue to perform its function of generating electricity from incident radiation (e.g. light).

The layered structure 12 comprises a multi-layer semiconductor assembly 60 including a photovoltaic element 62 which is sandwiched between an emitter layer 64 and a back surface field layer 66. As such, the emitter layer 64 and the back surface field layer 66 are arranged at opposite sides of the photovoltaic element 62.

The emitter layer 64 is arranged towards the front surface 16 of the layered structure 12 and the back surface field layer 66 is arranged towards the back surface 20. The front electrode assembly 14 is electrically connected to the emitter layer 64 and the back electrode assembly 18 is electrically connected to the back surface field layer 66. Such an arrangement defines a heterojunction technology (HJT) type solar cell.

The photovoltaic element 62 is formed of crystalline silicon (c-Si), which is negatively doped (i.e. an n-type material), with impurities of a group V element, such as phosphor (P), arsenic (As), and antimony (Sb). The emitter layer 64 and the back surface field layer 66 are each formed of amorphous silicon (a-Si:H). The amorphous silicon is deposited on the front and back surfaces of the silicon wafer using PECVD.

The emitter layer 64 comprises a positively doped semiconductor material (i.e. a p-type material), and the back surface field layer 66 comprises an n-type material. The p-type material contains impurities of a group III element such as boron (B), gallium (Ga), and indium (In).

According to the exemplary arrangement of the layered structure 12, the emitter layer 64 defines an impurity region of the layered structure having an opposite conductive type to that of the photovoltaic element 62, and thus forms a p-n junction along with the photovoltaic element 62.

The multi-layer semiconductor assembly 60 further comprises first and second intrinsic layers 74, 76. Both intrinsic layers 74, 76 are formed of intrinsically doped amorphous silicon. The first intrinsic layer 74 is arranged between the emitter layer 64 and the photovoltaic element 62 to form a front-side passivation layer. In addition, the second intrinsic layer is arranged between the photovoltaic element 62 and the back surface field layer 66 to form a back-side passivation layer.

Finally, the front surface 16 of the layered structure 12 is covered with transparent conductive coating 68, which is formed of indium tin oxide (ITO). An upper surface 70 of the ITO layer is textured to provide anti-reflective characteristics. The anti-reflection layer advantageously reduces the reflectance of light incident on the solar cell and increases selectivity of a predetermined wavelength band, thereby increasing the efficiency of the solar cell.

The back surface 20 of the layered structure 12 is also covered with a transparent conductive coating 72 formed of indium tin oxide (ITO). The transparent conductive coatings 68, 72 are configured to increase lateral carrier transport to finger electrodes arranged on the respective surfaces of the layered structure 12. The transparent conductive coatings 68, 72 are particularly advantageous in heterojunction type devices which comprise layers formed of amorphous silicon which exhibit poor carrier mobility.

During operation of the solar cell 10 light is incident upon the layered structure, as shown by the arrows at the top of FIG. 3. A plurality of electron-hole pairs are produced through the absorption of the incident photons. The electron-hole pairs are then separated into electrons and holes by a built-in potential difference resulting from the p-n junction. The separated electrons move to the n-type semiconductor in the photovoltaic element 62, and the separated holes move to the p-type semiconductor in the emitter layer 64. Accordingly, the electrons become major carriers in the photovoltaic element 62, and the holes become major carriers in the emitter layer 64. Each of these majority carriers are extracted from the layered structure 12 by the respective electrodes 14, 18.

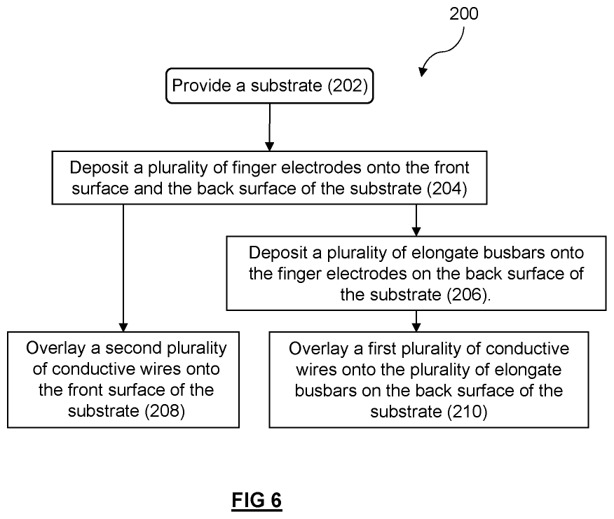

An exemplary method 200 of manufacturing the solar cell 10 will now be described with reference to FIG. 6, which illustrates a flow chart of the corresponding method steps.

The method commences with a first step 202 in which a layered structure 12 comprising a photovoltaic element is provided. According to an exemplary arrangement, the layered structure 12 is configured to comprise the semiconductor assembly 60, as described above with reference to FIG. 3.

The method then proceeds to step 204 in which the front and back surfaces 16, 20 of the layered structure 12 are each configured with a conductive portion. This is achieved through the deposition of electrically conductive material onto the front and back surfaces 16, 20 of the layered structure to form the pluralities of front and back finger electrodes 26, 34, respectively.

Once the plurality of back finger electrodes 34 are deposited onto the back surface 20 of the layered structure 12, the method can proceed with step 206 in which a plurality of elongate busbars 32 are deposited onto the layered structure 12. The busbars 32 are formed by depositing an electrically conductive material in a predetermined pattern onto the back surface 20 of the layered structure 12. In particular, the method comprises configuring the busbars 32 to lay perpendicular to the plurality of back finger electrodes 34, such that they form an electrical connection therewith.

Each of the pluralities of front and back finger electrodes 26, 34, and the plurality of elongate busbars 32, are deposited onto their respective surfaces using a screen-printing process. The screen-printing process includes laying down a printable precursor onto the layered structure surface through a screen, or mask. Openings in the mask determine the respective arrangement and dimensions of the printed features (i.e. the finger electrodes and busbars). Once each of the respective printable precursors is provided onto the layered structure surface, it is then fired in a furnace in order to form the corresponding finger electrodes and/or elongate busbar features.

The method of depositing the plurality of back finger electrodes 34 comprises depositing a first electrically conductive material onto the back surface 20. The method comprises depositing a first printable precursor, which is then cured according to a first firing process.

The method of depositing the plurality of elongate busbars 32 comprises depositing a second electrically conductive material onto the back surface 20 of the layered structure 12. The method comprises depositing a second printable precursor, which is then cured according to a second firing process.

The method of depositing the plurality of front finger electrodes 26 comprises depositing a third electrically conductive material onto the front surface 16. The method comprises depositing a third printable precursor, which is then cured according to a third firing process.

Owing to the arrangement of the busbars 32 relative to the back finger electrodes 34, the second printable precursor is only deposited onto the back surface 20 of the layered structure 12 once the plurality of back finger electrodes 34 have been formed, (i.e. after the first firing step is completed).

The first printable precursor is deposited using a different printing mask to that which is used to deposit the second printable precursor, corresponding to the back finger electrodes 34. The different printing mask comprises openings with different dimensions which alter the alignment and dimensions of the resulting busbars 32, relative to that of the finger electrodes 34.

Each of the first, second and third printable precursors comprise a metal paste which is obtained by mixing metal powder together with glass frit in the presence of a suitable solvent.

The pluralities of front and back finger electrodes 26, 34 are substantially the same. Hence, the first and third printable precursors are comprised of substantially the same chemical composition. Furthermore, the first and third firing processes each have the same firing parameters (e.g. firing temperature and duration).

The plurality of busbars 32 are formed of a composition which is different to that of the front and back finger electrodes 26, 34. Therefore, the second printable precursor is substantially different to that of the first and third printable precursors. Furthermore, the first firing process comprises different firing parameters to that of the second and third firing processes.

As part of the above described method, the elongate busbars 32 are arranged at predetermined locations on the back surface 20 of the layered structure 12 such that they can be overlaid with the first plurality of conductive wire portions 28. The method comprises a pre-alignment step in which the busbars 32 are positioned on the back surface 20 to ensure that the wire portions 28 will be accurately overlaid onto the busbars 32 during the subsequent method steps 208, 210.

Once the elongate busbars 32 are deposited onto the back surface 20 of the layered structure 12 (i.e. after the busbars 32 have been fired), the first plurality of conductive wire portions 28 can then be overlaid on top of the busbars 32. First, each of the wire portions 28 is axially aligned with a corresponding busbar 32 which is configured to receive the wire portion 28. Then, once each of the first plurality of conductive wire portions 28 is suitably aligned with an associated busbar 32, the wire portions 28 are placed onto the busbars 32 in method step 210.

According to the above described method, an axial length of each wire portion 28 is arranged parallel with an axial length of the busbar 32 upon which it is overlaid. Furthermore, each of wire portions 28 is arranged perpendicular to the plurality of finger electrodes 26, 34 on the front and back surfaces 16, 20 of the layered structure 12, as shown in each of FIGS. 2C, 4A, 4B and 5.

Following the deposition of the plurality of elongate busbars 32, the second plurality of conductive wire portions 22 may also arranged onto the layered structure 12. In step 208, the wire portions 22 are overlaid onto the front surface 18 of the layered structure 12 such that they sit perpendicular to the front plurality of finger electrodes 26 on the front surface 16 of the layered structure 12, as shown in FIG. 2A. The method of overlaying the first and second plurality of wire portions 28, 22 may proceed simultaneously or sequentially, and in any order.

The method of arranging the conductive wire portions 28, 22 includes the step of heating the wire portions 28, 22 in a furnace in order to bond the wire portions to the surface upon which they are overlaid. The first and second plurality of wire portions 28, 22 are each configured with an outer coating which partially melts when heated.

The outer coating on the wire portions of the second plurality of conductive wire portions 22 is configured to form an ohmic contact with the underlying finger electrodes 26 arranged on the front surface 16 of the layered structure 12, whereas heating the first plurality of conductive wire portions 28 causes the coatings to form an ohmic contact with the elongate busbars 32 arranged on the back surface 20.

It will be understood that the invention is not limited to the embodiments above-described and various modifications and improvements can be made without departing from the concepts described herein. Except where mutually exclusive, any of the features may be employed separately or in combination with any other features and the disclosure extends to and includes all combinations and sub-combinations of one or more features described herein.

1. A solar cell assembly comprising;
a layered structure comprising a photovoltaic element; and
an electrode assembly arranged on a surface of the layered structure, the electrode assembly comprising;
a plurality of conductive wire portions,
a first plurality of conductive elements arranged on the surface of the layered structure; and
a second plurality of conductive elements interposed between the plurality of conductive wire portions and the first plurality of conductive elements;
wherein the first plurality of conductive elements are configured to form an ohmic contact between the second plurality of conductive elements and the surface of the layered structure, and the second plurality of conductive elements are configured to form an ohmic contact between the first plurality of conductive elements and the plurality of conductive wire portions.

2. The solar cell assembly according to claim 1, wherein the electrode assembly defines a back electrode assembly which is arranged on a back surface of the layered structure, the solar cell assembly further comprising a front electrode assembly arranged on a front surface of the layered structure opposite the back surface.

3. The solar cell assembly according to claim 2, wherein the plurality of conductive wire portions of the back electrode assembly define a first plurality of conductive wire portions, wherein the front electrode assembly comprises a second plurality of conductive wire portions, the second plurality of conductive wire portions is configured to form an ohmic contact with a third plurality of conductive elements of the front electrode assembly, the third plurality of conductive elements being interposed between the second plurality of conductive wire portions and the front surface of the layered structure.

4. The solar cell assembly according to claim 3, wherein only the back electrode assembly comprises a second plurality of conductive elements interposed between a plurality of conductive wire portions and a first plurality of conductive elements.

5. The solar cell assembly according to claim 4, wherein the second plurality of conductive elements define a plurality of elongate busbars.

6. The solar cell assembly according to claim 5, wherein at least one conductive wire portion of the plurality of conductive wire portions is arranged to at least partly overlay at least one elongate busbar of the plurality of elongate busbars.

7. The solar cell assembly according to claim 6, wherein the elongate busbar is arranged substantially in parallel with the conductive wire portion.

8. The solar cell assembly according to claim 7, wherein at least one of the plurality of elongate busbars has a width which is measured in the plane of the surface of the layered structure, the width of the elongate busbar is at least equal to a thickness of the conductive wire portion measured in the plane of the surface of the layered structure.

9. The solar cell assembly according to claim 8, wherein the width of the elongate busbar is substantially the same, or smaller, than the thickness of the conductive wire portion.

10. The solar cell assembly according to claim 8, wherein the width of the elongate busbar is less than 0.7 mm.

11. The solar cell assembly according to claim 8, wherein the width of a first portion of the elongate busbar is greater than the thickness of the conductive wire portion, and/or wherein the width of a second portion of the elongate busbar is substantially the same as the thickness of the conductive wire portion, and/or wherein the width of a third portion of the elongate busbar is smaller than the thickness of the conductive wire portion.

12. The solar cell assembly according to claim 8, wherein the width of the elongate busbar varies along its length.

13. The solar cell assembly according to claim 12, wherein a longitudinal edge of the elongate busbar comprises a plurality of straight or curved facets.

14. The solar cell assembly according to claim 12, wherein the width of the elongate busbar varies along its length to define a diamond or scalloped shape.

15. The solar cell assembly according to claim 14, wherein each of the wire portions of the first plurality of conductive wire portions is configured to overlay a corresponding conductive element of the plurality of elongate busbars.

16. The solar cell assembly according to claim 15, wherein an axial length of each of the wire portions of the first plurality of conductive wire portions is configured to be substantially parallel to an axial length of a corresponding conductive element of the plurality of elongate busbars upon which they are overlaid.

17. The solar cell assembly according to claim 16, wherein the first plurality of conductive elements comprises a plurality of finger electrodes, wherein at least one of the plurality of finger electrodes is substantially misaligned in a lengthwise direction with at least one of the plurality of elongate busbars which overlap the finger electrode.

18. The solar cell assembly according to claim 17, wherein the at least one finger electrode is arranged substantially perpendicularly with respect to the at least one elongate busbar.

19. The solar cell assembly according to claim 4, wherein at least one of the first and second pluralities of conductive elements are formed using a printed material.

20. A solar module comprising a plurality of solar cell assemblies according to claim 1, wherein the plurality of solar cell assemblies are electrically coupled together.

21. A solar module according to claim 20, comprising a first solar cell assembly electrically coupled to a second solar cell assembly, wherein the plurality of conductive wire portions of the first solar cell assembly are electrically coupled to the plurality of conductive wire portions of the second solar cell assembly.

22. A method for manufacturing a solar cell assembly comprising:
providing a layered structure comprising a photovoltaic element; and
arranging an electrode assembly onto a surface of the layered structure, wherein arranging the electrode assembly comprises:
configuring a first plurality of conductive elements onto the surface of the layered structure to form an ohmic contact therewith;
configuring a second plurality of conductive elements onto the first plurality of conductive elements to form an ohmic contact therewith; and
arranging a plurality of conductive wire portions onto the second plurality of conductive elements to form an ohmic contact therewith.

23. The method according to claim 22, wherein the layered structure comprises a back surface and a front surface being opposite the back surface; wherein the method comprises arranging the electrode assembly onto the back surface to define a back electrode assembly; and, wherein the method further comprises arranging a front electrode assembly onto the front surface.

24. The method according to claim 23, wherein the plurality of conductive wire portions of the back electrode assembly define a first plurality of conductive wire portions, wherein arranging the front electrode assembly comprises;
configuring a third plurality of conductive elements onto the front surface of the layered structure to form an ohmic contact therewith; and
arranging a second plurality of conductive wire portions onto the third plurality of conductive elements to form an ohmic contact therewith.

25. The method according to claim 24, wherein only the method of arranging the back electrode assembly comprises configuring a second plurality of conductive elements interposed between a plurality of conductive wire portions and a first plurality of conductive elements.

26. The method according to claim 25, wherein configuring the first plurality of conductive elements comprises depositing a first printed material onto the surface of the layered structure to form a plurality of finger electrodes.

27. The method according to claim 26, wherein configuring the second plurality of conductive elements comprises depositing a second printed material onto the surface of the layered structure to form a plurality of elongate busbars.

28. The method according to claim 27, wherein depositing the first printed material comprises depositing a first printable precursor and then firing the first printable precursor according to a first firing process, and wherein depositing the second printed material comprises depositing a second printable precursor and then firing the second printable precursor according to a second firing process, wherein the first printable precursor is only deposited onto the surface of the layered structure after the second firing process is complete.
